(19) United States
(12) Patent Application Publication
(10) Pub. No.: US 2008/0182021 A1
(43) Pub. Date: Jul. 31, 2008

(54) Continuous ultra-thin copper film formed using a low thermal budget

(76) Inventors: Harsono S. Simka, Saratoga, CA (US); Joseph H. Han, San Jose, CA (US); Adrien R. Lavoie, Beaverton, OR (US); Juan E. Dominguez, Hillsboro, OR (US); John J. Plombon, Portland, OR (US)

Correspondence Address: INTEL CORPORATION;c/o INTELLEVATE, LLC, P.O. BOX 52050, MINNEAPOLIS, MN, 55402, US

(21) Appl. No.: 11/701,301

(22) Filed: Jan. 31, 2007

(51) Int. Cl. C23C 16/00

(52) U.S. Cl. 427/248.1

(57) ABSTRACT

A method for forming a continuous ultra-thin copper layer using a low thermal budget comprises providing a substrate in a reactor, establishing a low first temperature at a surface of the substrate, introducing a copper precursor flow into the reactor to deposit the copper precursor onto the surface, introducing an inert gas flow into the reactor after the copper precursor flow, increasing the temperature at the surface of the substrate to a second temperature during the inert gas flow, and performing a chemical vapor deposition process at the second temperature to deposit a copper layer on the substrate.

### BACKGROUND

In the manufacture of integrated circuits, copper interconnects are generally formed on a semiconductor substrate using a copper dual damascene process. Such a process begins with a trench being etched into a dielectric layer and filled with a barrier layer, an adhesion layer, and a seed layer. A physical vapor deposition (PVD) process, such as a sputtering process, may be used to deposit a tantalum nitride (TaN) barrier layer and a tantalum (Ta) or ruthenium (Ru) adhesion layer (i.e., a TaN/Ta or TaN/Ru stack) into the trench. The TaN barrier layer prevents copper from diffusing into the underlying dielectric layer. The To or Ru adhesion layer is required because the subsequently deposited metals do not readily nucleate on the TaN barrier layer. This may be followed by a PVD sputter process to deposit a copper seed or a copper-aluminum alloy layer into the trench. An electroplating process is then used to fill the trench with copper metal to form the interconnect.

As device dimensions scale down, the aspect ratio of the trench becomes more aggressive as the trench becomes narrower. This gives rise to issues such as trench overhang during the PVD copper seed deposition, leading to pinched-off trench openings during plating and inadequate gapfill. Additionally, as trenches decrease in size, the ratio of barrier metal to copper metal in the overall interconnect structure increases, thereby increasing the electrical line resistance and RC delay of the interconnect.

The use of chemical vapor deposition (CVD) techniques (or atomic layer deposition (ALD) techniques which are a subset of CVD) also has some drawbacks, such as copper agglomeration and poor gap-fill. Accordingly, alternative techniques are needed to address these issues that occur during the deposition of the copper seed layer.

### BRIEF DESCRIPTION OF THE DRAWINGS

FIGS. 1A to 1B illustrate a conventional damascene process for forming metal interconnects.

FIG. 2 is a method of forming a copper seed layer using surface nucleation in accordance with an implementation of the invention.

FIG. 3 is a method of forming a copper seed layer under a continuously varying temperature in accordance with an implementation of the invention.

FIG. 4 is a method of forming a copper seed layer with temperature ramp surface activation in accordance with an implementation of the invention.

FIG. 5 is a method of forming a copper seed layer with electron beam surface activation in accordance with an implementation of the invention.

FIG. 6 is a method of forming a copper seed layer with free radical surface activation in accordance with an implementation of the invention.

FIG. 7 is a method of forming a copper seed layer with surface activation in the presence of a reducing agent in accordance with an implementation of the invention.

### DETAILED DESCRIPTION

Described herein are systems and methods of forming ultra thin copper seed layers with low thermal budgets. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention; however, the order of description should not be construed to imply that these operations are necessarily order dependent. In particular, these operations need not be performed in the order of presentation.

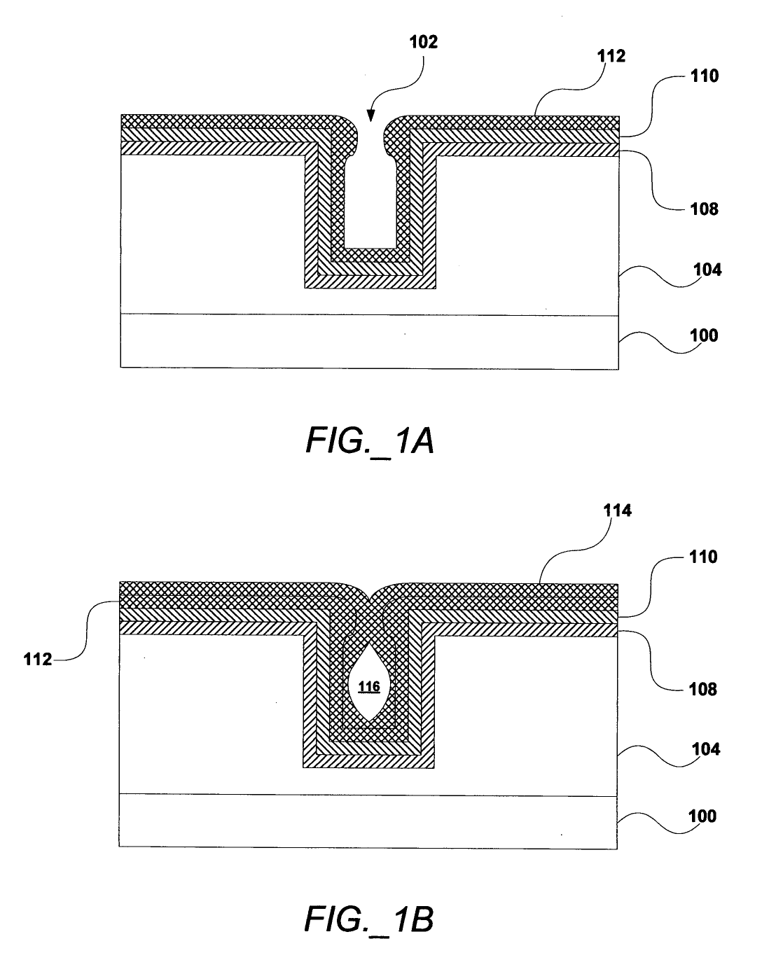

For reference, FIGS. 1A to 1B illustrate a conventional damascene process for fabricating copper interconnects on a semiconductor wafer. FIG. 1A illustrates a substrate 100, such as a semiconductor wafer, that includes a trench 102 that has been etched into a dielectric layer 104. A conventional barrier layer 108 and adhesion layer 110 are conformally deposited on the dielectric layer 104 and within the trench 102. The barrier layer 108 is generally formed from tantalum nitride (TaN). The adhesion layer 110 is generally formed from tantalum (Ta) or ruthenium (Ru).

After the adhesion layer 110 is formed, the conventional damascene process uses two independent deposition processes to fill the trench 102 with copper metal. The first deposition process is a PVD process that forms a non-conformal copper seed layer 112, which is shown in FIG. 1A and enables a subsequent plating process to fill the trench 102 with copper metal. As shown, the PVD process may cause some trench overhang to occur in the copper seed layer 112 that narrows the width of the trench 102. The second deposition process is a plating process, such as an electroplating (EP) or electroless plating (EL) process, that deposits a bulk copper layer 114 to fill the trench 102.

FIG. 1B illustrates the trench 102 after an EP or EL copper deposition process has been carried out. Due to the narrow width of the trench 102, issues such as trench overhang and pinching off of the trench opening occur that lead to defects in the plating step. As shown in FIG. 1B, such defects include a void 116 that will now appear in the final metal interconnect after the excess metal disposed outside of the trench 102 is removed during a subsequent planarization step.

Conventional thermal chemical vapor deposition (CVD) and atomic layer deposition (ALD) processes for generating copper seed layers have been used to replace the PVD process, but such processes tend to suffer from issues such as copper agglomeration and poor gap-fill. For instance, conventional thermal copper CVD processes may use high deposition rates that often lead to agglomeration (i.e., the copper film breaking up into copper “droplets”). Furthermore, conventional thermal copper CVD processes may alternately use a low deposition rate that often leads to nucleation issues and 3-D island growth. In some processes, organometallic precursors may be used that include fluorine and/or oxygen, but they produce impure and highly resistive films with poor adhesion.

It has been shown that a high thermal budget deposition process can have detrimental effects on a thin copper seed layer. Therefore, to improve upon conventional methods for fabricating copper seed layers, implementations of the invention use a low thermal budget process that reduces copper agglomeration and enables CVD and ALD depositions of thin copper seed layers. The thickness of the copper layers formed using implementations of the invention may be less than 10 nanometers (nm). Copper layers formed in accordance with implementations of the invention tend to be continuous, tend to have high nucleation density leading to relatively smooth surfaces compared to conventional copper seed layers, and have low resistivity.

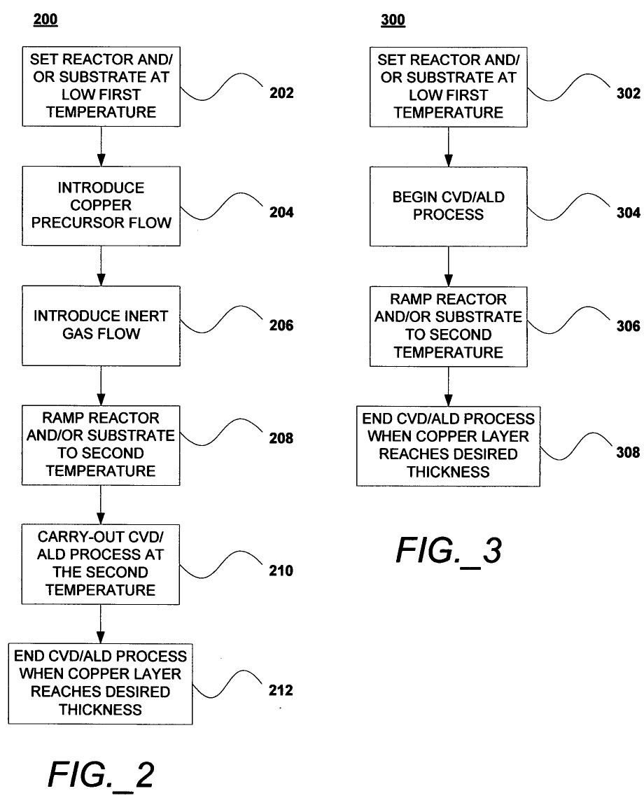

FIG. 2 is a method 200 of forming a copper layer using a low thermal budget in accordance with an implementation of the invention. The method 200 uses a surface nucleation or pre-treatment process. As will be well known to those of skill in the art, the copper deposition process will typically occur within a reactor, such as a CVD or ALD reactor, and will occur on a substrate such as a semiconductor wafer.

The method 200 begins by setting the reactor and/or the substrate at a low first temperature (process 202 of method 200). In some implementations of the invention, this first temperature may be between around 0° C. and around 80° C., with the temperature typically falling between 50° C. and 60° C. For all practical purposes, both the reactor and the substrate will be set at the low first temperature. Some implementations may reduce the temperature directly at the substrate location while other implementations may reduce the reactor temperature, which will in turn reduce the substrate temperature.

Next, a copper precursor is flowed into the reactor to cause a low temperature nucleation of copper precursor on the substrate surface (204). A wide variety of copper precursors may be used here, and several examples of copper precursors are provided below.

In some implementations of the invention, the following process parameters may be used for the copper precursor flow. The reactor pressure may be between around 0.1 Torr and 3.0 Torr, and generally falls between 1.5 Torr and 2.0 Torr. The reactor temperature (e.g., the chuck or susceptor temperature) may be between around 25° C. and 75° C., and generally falls between 40° C. and 60° C. The copper precursor may be in a volatile state with a flow rate between around 0.1 cubic feet/minute (ft³/min) and 1.0 ft³/min, and typically falls around 0.4 ft³/min. The copper precursor temperature may be between around 50° C. and around 125° C., and typically falls between 75° C. and 85° C. The delivery line temperature may range from 50° C. to around 130° C., the shower head temperature may range from around 70° C. to around 130° C., and the vaporizer temperature may range from around 50° C. to around 125° C.

A carrier gas may be employed to move the copper precursor at a temperature that generally ranges from around 75° C. to around 105° C. and a flow rate that ranges from around 100 SCCM to around 200 SCCM. Carrier gases that may be used include, but are not limited to, argon, xenon, and helium. The process may also include a hydrogen flow with a flow rate between 200 SCCM to around 600 SCCM, with a hydrogen flow rate typically falling around 300 SCCM.

A plasma preclean may be used with a plasma power that ranges from around 50 W to around 500 W, and typically falls between 140 W and 200W. The plasma preclean may occur for a time duration of between 1 and 30 seconds.

The copper precursor flow at the low first temperature pre-treats the surface of the substrate with the copper precursor. After the surface pretreatment, the copper precursor flow is halted and an inert gas is flowed into the reactor (206). In various implementations of the invention, the inert gas used may be any known inert gas used in semiconductor manufacturing processes, including but not limited to argon, xenon, nitrogen, helium, or forming gas.

While under the flow of inert gas, the temperature of the reactor and/or substrate is ramped up to a second temperature (208). Again, the temperature may be increased directly at the substrate location or the reactor temperature may be increased, which will in turn increase the substrate temperature. In various implementations of the invention, the second temperature that the substrate is elevated to may fall between around 60° C. and 150° C.

Next, at the elevated second temperature, a conventional CVD or ALD process may be carried out to deposit copper metal onto the substrate (210). CVD and ALD processes are well known to those of skill in the art. Conventional CVD and ALD process parameters may be used here with a reactor temperature that is below 150° C. The copper CVD process generally consists of flowing a copper precursor and a co-reactant into the reaction chamber where they react to form a copper layer on the substrate. The CVD process continues until the deposited copper layer achieves a desired thickness. Similarly, the copper ALD process generally consists of separately introducing discrete pulses of the copper precursor and the co-reactant into the reactor where they react to form a copper layer on the substrate. Purge pulses of an inert gas are introduced between each of the precursor and the co-reactant pulses. The cycle of precursor pulse-purge pulse-co-reactant pulse-purge pulse is repeated until the copper layer reaches a desired thickness. Co-reactants that may be used in the CVD or ALD processes described here are provided below.

The CVD or ALD process may be halted when the deposited copper layer reaches the desired thickness (212). In implementations of the invention, because an ultra-thin copper layer is being formed, the desired thickness may be between around 1 nm and 10 nm. The copper layer formed in accordance with this implementation may now be used as a copper seed layer in a metal interconnect fabrication process.

FIG. 3 is a method 300 of forming a copper layer using a low thermal budget in accordance with another implementation of the invention. Again, the copper deposition process will typically occur within a reactor and will occur on a substrate such as a semiconductor wafer.

The method 300 begins by setting the reactor and/or the substrate at a low first temperature (process 302 of method 300). In some implementations of the invention, this first temperature may be less than 80° C., for instance, the first temperature may be between around 0° C. and 50° C. For all practical purposes, both the reactor and the substrate will be set at the low first temperature. Some implementations may reduce the temperature directly at the substrate location while other implementations may reduce the reactor temperature, which will in turn reduce the substrate temperature.

Next, a conventional CVD or ALD process is carried out to deposit copper metal onto the substrate (304). CVD and ALD processes are well known to those of skill in the art and were described above. Copper precursors and co-reactants that may be used here are provided below.

While the CVD or ALD process is being carried out, the temperature of the reactor and/or substrate is ramped up to a second temperature (306). Again, the temperature may be increased directly at the substrate location or the reactor temperature may be increased, which will in turn increase the substrate temperature. The second temperature that the substrate is elevated to may fall between around 80° C. and 150° C. In various implementations of the invention, the substrate temperature may be increased to the second temperature at a controlled rate that may be either linear or non-linear.

Finally, the CVD or ALD process may be halted when the deposited copper layer reaches the desired thickness (308). As before, in implementations of the invention, the desired thickness may be between around 1 nm and 10 nm.

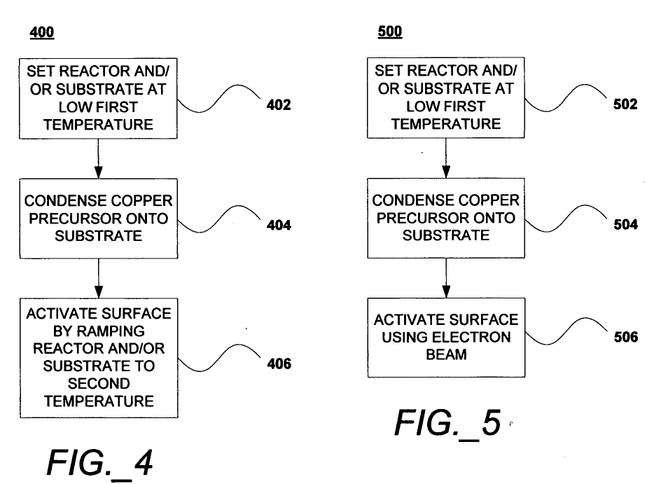

FIG. 4 is a method 400 of forming a copper layer using a low thermal budget in accordance with another implementation of the invention. The method 400 uses a copper condensation process. Again, the copper deposition process will typically occur within a reactor, such as a CVD or ALD reactor, and will occur on a substrate such as a semiconductor wafer.

The method 400 begins by setting the reactor and/or the substrate at a low first temperature (process 402 of method 400). In some implementations of the invention, this first temperature may range from 0° C. to 50° C. For all practical purposes, both the reactor and the substrate will be set at the low first temperature. Some implementations may reduce the temperature directly at the substrate location while other implementations may reduce the reactor temperature, which will in turn reduce the substrate temperature.

Next, a copper precursor is condensed onto the surface of the substrate (404). A wide variety of copper precursors may be used here, and several examples of copper precursors are provided below. The condensation may be carried out by flowing a relatively high temperature copper precursor into the reactor and allowing it to condense on a relatively low temperature surface of the substrate. For example, one or more cycles of a copper precursor and carrier gas mixture may be introduced into the reactor when the substrate is at a low temperature and the precursor delivery lines are maintained at a sufficient temperature to avoid precursor condensation in the lines.

Finally, the copper precursor is activated by ramping the reactor and/or substrate to a second temperature (406). The second temperature that the substrate is elevated to may fall between around 80° C. and around 150° C. In various implementations of the invention, the substrate temperature may be increased to the second temperature at a controlled rate that may be either linear or non-linear, or the temperature ramp may consist of a rapid thermal flash. Co-reactants, as described below, may be added during this process.

Activation of the copper precursor through temperature ramping or thermal flash leads to precursor decomposition, ligand removal, and copper layer formation. A desired thickness for the copper layer may be between around 1 nm and 10 nm and is achieved by controlling the amount of copper precursor that is condensed onto the substrate surface, final temperature target, ramp rate, or thermal energy input.

FIG. 5 is a method 500 of forming a copper layer using a low thermal budget in accordance with another implementation of the invention. The method 500 uses a copper condensation process and begins by setting the reactor and/or the substrate at a low first temperature that may range from 0° C. to 50° C. (process 502 of method 500). Next, a copper precursor is condensed onto the surface of the substrate (504). Several examples of copper precursors are provided below.

Finally, the copper precursor is activated using an electron beam (506). The electron beam causes precursor decomposition, ligand removal, and copper layer formation. A desired thickness for the copper layer may be between around 1 nm and 7 nm and is achieved by controlling the amount of copper precursor that is condensed onto the substrate surface and/or controlling the intensity of the electron beam.

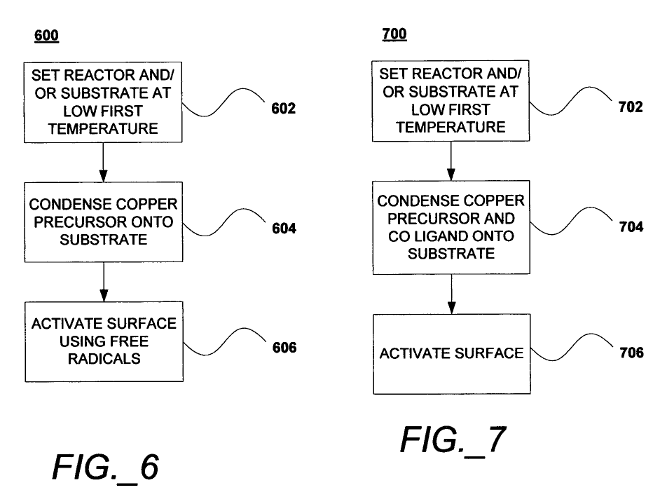

FIG. 6 is a method 600 of forming a copper layer using a low thermal budget in accordance with another implementation of the invention. The method 600 uses a copper condensation process and begins by setting the reactor and/or the substrate at a low first temperature that may range from 0° C. to 50° C. (process 602 of method 600). Next, a copper precursor is condensed onto the surface of the substrate (604). Several examples of copper precursors are provided below.

Finally, the copper precursor is activated using thermal reactions with free radicals (606). The free radicals cause ligand desorption and copper deposition. A desired thickness for the copper layer may be between around 1 nm and 7 nm and is achieved by controlling the amount of copper precursor that is condensed onto the substrate surface. In some implementations, the free radicals may be generated from a co-reactant using a plasma and/or a hot filament.

FIG. 7 is a method 700 of forming a copper layer using a low thermal budget in accordance with another implementation of the invention. The method 700 uses a copper condensation process and begins by setting the reactor and/or the substrate at a low first temperature that may range from 0° C. to 50° C. (process 702 of method 700). Next, a copper precursor and a carbon monoxide co-reactant are condensed onto the surface of the substrate (704). Several examples of copper precursors are provided below.

Finally, the copper precursor is activated using any of the methods described above, such as temperature ramping, rapid thermal flash, electron beam, or free radicals (706). During activation, the carbon monoxide functions as a reducing agent to react and remove contaminants. The surface residence time of the carbon monoxide may be increased by using low or zero purge gas flow in the reactor during and/or after the copper precursor activation. A desired thickness for the copper layer may be between around 1 nm and 10 nm and is achieved by controlling the amount of copper precursor that is condensed onto the substrate surface.

In accordance with implementations of the invention, copper precursors that may be used in the methods described above include, but are not limited to, Cu(CO)₃, Cu₂(CO)ₓ, CpCu(CO), (C₅HR₄)Cu(CO) where R=CHMe₂, and other carbonyl based precursors. Also, in accordance with implementations of the invention, co-reactants that may be used in the methods described above include, but are not limited to, hydride containing co-reactants such as H₂, SiH₄, NH₃, N₂H₄, and B₂H₆.

It should be noted that in the various methods described herein, the substrate that the copper layer is deposited upon may consist of a semiconductor substrate, such as a semiconductor wafer. In implementations of the invention, the semiconductor substrate may be formed using a bulk silicon or a silicon-on-insulator substructure. In other implementations, the substrate may be formed using alternate materials, which may or may not be combined with silicon, that include but are not limited to germanium, indium antimonide, lead telluride, indium arsenide, indium phosphide, gallium arsenide, gallium antimonide, or other Group III-V materials. Although a few examples of materials from which the semiconductor substrate may be formed are described here, any material that may serve as a foundation upon which a semiconductor device may be built falls within the spirit and scope of the present invention.

The semiconductor substrate may have at least one dielectric layer deposited on its surface. The dielectric layer may be formed using materials known for the applicability in dielectric layers for integrated circuit structures, such as low-k dielectric materials. Such dielectric materials include, but are not limited to, silicon dioxide (SiO₂), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The dielectric layer may include pores or other voids to further reduce its dielectric constant. The dielectric layer may include one or more trenches and/or vias within which the copper seed layer will be deposited. The trenches and/or vias may be patterned using conventional wet or dry etch techniques that are known in the art.

Accordingly, implementations of the invention have been described for forming smooth, thin, and low resistivity copper seed layers using low temperature nucleation or condensation processes. Unlike conventional processes where the substrate is maintained at the elevated second temperature for the entire duration of the process, implementations described herein begin at a low first temperature and then utilize a ramping of the reactor and/or substrate temperature to increase the deposition rate and reduce contaminants. This enables the overall thermal budget of the deposition process to be dramatically reduced, which in turn causes less damage to the deposited copper seed layer. As described above, some implementations use electron-flux, electron beam, or free radical assisted reactions of copper precursor that has been adsorbed onto the substrate surface using the low temperature condensation processes. In further implementations, carbon monoxide may be added to the copper precursor to function as a reducing agent during the deposition processes.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. A method comprising:
providing a substrate in a reactor;
establishing a low first temperature at a surface of the substrate;
introducing a copper precursor flow into the reactor to deposit the copper precursor onto the surface;
introducing an inert gas flow into the reactor after the copper precursor flow;
increasing the temperature at the surface of the substrate to a second temperature during the inert gas flow; and
performing a chemical vapor deposition process at the second temperature to deposit a copper layer on the substrate.

2. The method of claim 1, wherein the first temperature is less than 80° C.

3. The method of claim 1, wherein the second temperature is between around 60° C. and around 150° C.

4. The method of claim 1, wherein the chemical vapor deposition process comprises an atomic layer deposition process.

5. A method comprising:
providing a substrate in a reactor;
establishing a low first temperature at a surface of the substrate;
performing a chemical vapor deposition process at the first temperature to deposit a copper layer on the substrate; and
increasing the temperature at the surface of the substrate to a second temperature during the chemical vapor deposition process.

6. The method of claim 5, wherein the first temperature is less than 80° C.

7. The method of claim 5, wherein the second temperature is between around 80° C. and around 150° C.

8. The method of claim 5, wherein the chemical vapor deposition process comprises an atomic layer deposition process.

9. A method comprising:
providing a substrate in a reactor;
establishing a low first temperature at a surface of the substrate;
condensing a copper precursor onto the surface of the substrate; and
activating the copper precursor.

10. The method of claim 9, wherein the first temperature is between around 0° C. and around 50° C.

11. The method of claim 9, wherein the condensing of the copper precursor onto the surface of the substrate comprises flowing the copper precursor into the reactor at a temperature that is relatively higher than the low first temperature of the substrate.

12. The method of claim 9, wherein the activating of the copper precursor comprises increasing the temperature of the substrate surface to a temperature between around 80° C. and around 150° C.

13. The method of claim 9, wherein the activating of the copper precursor comprises exposing the copper precursor to a rapid thermal flash.

14. The method of claim 9, wherein the activating of the copper precursor comprises exposing the copper precursor to an electron beam.

15. The method of claim 9, wherein the activating of the copper precursor comprises exposing the copper precursor to free radicals.
